(19) United States
(12) Patent Application Publication
(10) Pub. No.: US 2013/0076337 A1
(43) Pub. Date: Mar. 28, 2013

(54) Dynamic RF Power Measurement with Visualization

(71) Applicants: Mathew Lee, Oklahoma City, OK (US); Paul Beard, Bigfork, MT (US)

(72) Inventors: Mathew Lee, Oklahoma City, OK (US); Paul Beard, Bigfork, MT (US)

(73) Assignee: Dechnia, LLC, Colorado Springs, CO (US)

(21) Appl. No.: 13/208,018

(22) Filed: Sep. 26, 2011

(51) Int. Cl. G01R 22/00

(52) U.S. Cl. 324/76.11

(57) ABSTRACT

Embedded systems that utilize RF are often times difficult to troubleshoot as the signals cannot be easily probed without special equipment. Embodied in this patent is a tool that allows the embedded systems designer to troubleshoot these said RF designs. A combined spectrum analyzer and dynamic power meter. These are two of the most important tools that a designer needs when doing RF protocol development. This, coupled with an intuitive/simple to use graphical user interface, provides the ideal tool for RF engineering doing embedded systems design, product verification, and protocol design.

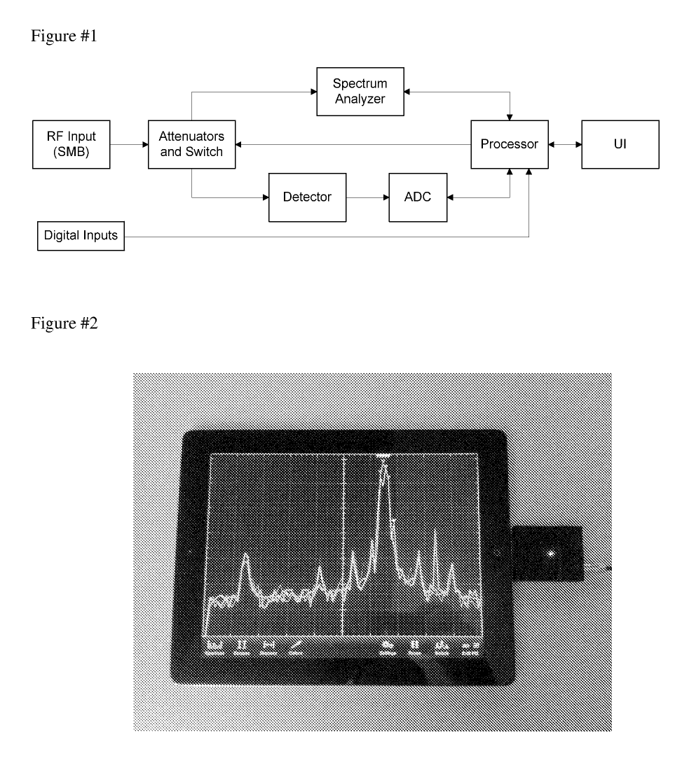

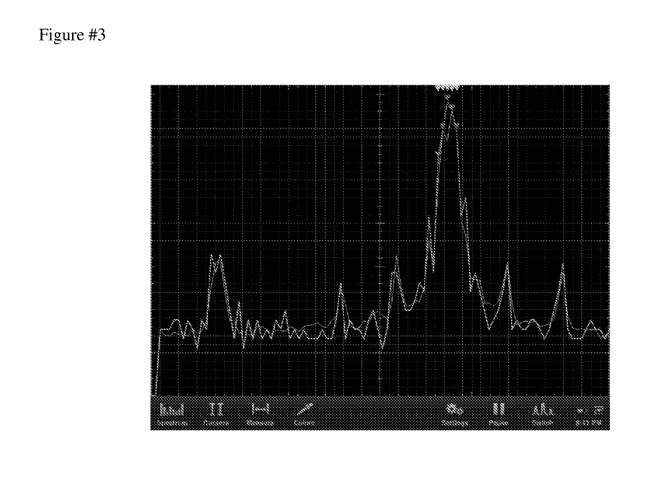

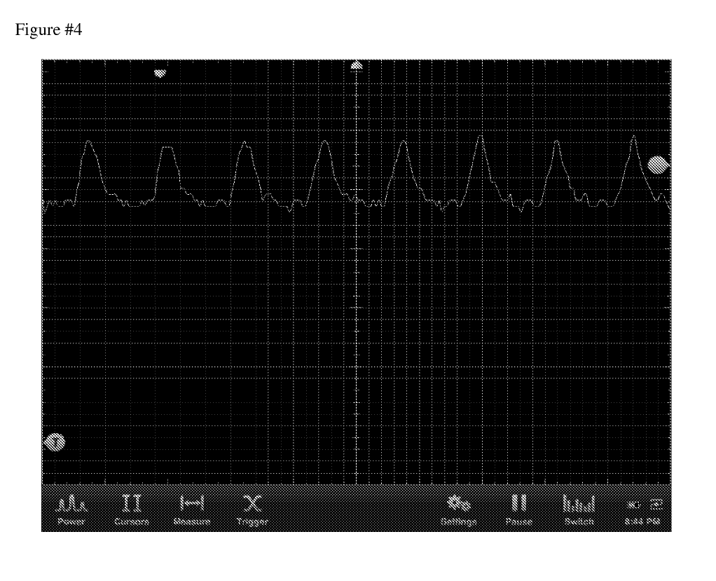

### FIELD

This invention related to the measurement of radio frequency (RF) power.

### BACKGROUND

Embedded systems that utilize RF are often times difficult to troubleshoot as the signals cannot be easily probed without special equipment. Embodied in this patent is a tool that allows the embedded systems designer to troubleshoot these said RF designs. A combined spectrum analyzer and dynamic power meter. These are two of the most important tools that a designer needs when doing RF protocol development. This, coupled with an intuitive/simple to use graphical user interface, provides the ideal tool for RF engineering doing embedded systems design, product verification, and protocol design.

Similar patents:

U.S. Pat. No. 7,049,805—May 23, 2006—Radio Frequency Power Measurement

U.S. Pat. No. 7.098.646—Aug. 29, 2006—Radio Frequency Power Generation and Power Measurement

U.S. Pat. No. 7,701,198—Apr. 20, 2010—Power Measurement Apparatus

### SUMMARY

Debugging of embedded systems that utilize RF requires several pieces of expensive equipment. The device described combines several of these important pieces of equipment into a single device. See block diagram in the drawings labeled FIG. #1.

The physical implementation of this design was built to run on a mobile platform. The hardware is modular and can be hot plugged into a smart-phone or other similar mobile computing device.

It is extremely portable and can be installed and removed at any time. The device has two significant measurement input ports; the first is an RF input (SMB) which allows for both conducted and radiated measurements to be performed when the appropriate adapter is installed. The second input port for the user to supply stimulation is the logic port (JST connectors) which allows the user to trigger on simplistic and complex events that are driven from a source other than RF. Attenuators can be activated to allow the measurement of both low and high power signals. Additional, a gain amplifier could be installed to look at very small signals. See picture of the hardware device installed in the drawings labeled FIG. #2.

The spectrum analyzer portion of this invention takes measurements of the amplitude at different frequencies and displays them on a graph where the user can identify important measurements such as the raw wave, max hold, raw with max hold, decay, raw with decay, average, raw with average, and waterfall. Measurements of the top peaks can be performed on the fly and identified graphically. See picture of the hardware device installed in the drawings labeled FIG. #3.

The power meter portion of the invention is comprised of a detector and an ADC and is used to take many samples in real time or around a triggered event of a given waveform. The controls and display can be manipulated (both in terms of amplitude or time) in a very similar manner to that of an oscilloscope. With our specific implementation, we use a touch screen to adjust the time base and gain scales. The digital inputs are exclusively used in the power meter mode and can be used to create triggered events in which to capture the RF data. RF data can also be used to directly trigger the event for capture. Pre and post trigger data is captured and displayed on the device much like a typical oscilloscope. Typical measurements such as min, max, mean, peak to peak, peak to average, rms, duty cycle (+), duty cycle (−), pulse width (+), pulse width (−), cycle mean, cycle rms, frequency, period, rise time, fall time can be made and displayed on the screen in real time. Cursors are also available for easy scrolling to a specific point in the data. See picture of the hardware device installed in the drawings labeled FIG. #4.

What is claimed is:

1. This invention allows one to view the power output with respect to time (dynamic power meter).

2. This invention combines the hardware so that one can look at both the spectrum and/or dynamic power output.

3. This invention transfers RF spectrum and dynamic power readings to a graphical interface located on a mobile platform.

4. This invention allows for the system or user to control which of the data readings are being taken at any given time.

5. This invention allows for external triggers to be applied that are not RF in nature.
